(19) United States
(12) Patent Application Publication
(10) Pub. No.: US 2019/0206908 A1
(43) Pub. Date: Jul. 4, 2019

(54) ARRAY SUBSTRATE AND METHOD FOR MANUFACTURING THE SAME

(71) Applicant: SHENZHEN CHINA STAR OPTOELECTRONICS TECHNOLOGY CO., LTD., Shenzhen, GD (CN)

(72) Inventor: Lixuan CHEN, Shenzhen (CN)

(21) Appl. No.: 15/763,940

(22) PCT Filed: Jan. 24, 2018
(86) PCT No.: PCT/CN2018/073920

§ 371 Date: Nov. 20, 2018

(30) Foreign Application Priority Data
Dec. 29, 2017 (CN) 201711498126.6

(51) Int. Cl. H01L 27/12

(52) U.S. Cl. CPC H01L 27/1288; H01L 27/1218; H01L 27/127

(57) ABSTRACT

The present disclosure provides an array substrate and a method for manufacturing the same. The method includes: forming a second conducting layer on a first conducting layer, wherein a second reflectivity of the second conducting layer is higher than a first reflectivity of the first conducting layer; forming an insulating layer on the second conducting layer; forming a photoresist layer covering a whole surface of the insulating layer; exposing and developing the photoresist layer to form a first connecting hole, wherein the first connecting hole exposes the insulating layer; forming a second connecting hole exposing the second conducting layer; and forming a third conducting layer on the photoresist layer, wherein the third conducting layer covers the first connecting hole and the second connecting hole and is in contact with the second conducting layer.

### CROSS-REFERENCE TO RELATED APPLICATIONS

The present application is a 35 U.S.C. § 371 National Phase conversion of International (PCT) Patent Application No. PCT/CN2018/073920, filed on Jan. 24, 2018, which claims foreign priority to Chinese Patent Application No.201711498126.6, filed on Dec. 29, 2017 in the State Intellectual Property Office of China, the entire contents of which are hereby incorporated by reference.

### TECHNICAL FIELD

The present disclosure generally relates to the display field, and in particular to an array substrate and a method for manufacturing the same.

### BACKGROUND

Today, the thin film transistor (TFT) is widely used in the display to drive the pixels. As a main component of the display, the array substrate is configured to provide driving circuit for the display and usually includes multiple gate electrode scan lines and data lines. The gate electrode scan lines and data lines cooperatively define multiple pixel units. Each of the pixel units includes a TFT component and a pixel electrode. The gate electrode of the TFT is connected with the gate electrode scan line. When the voltage on the gate electrode scan line reaches the threshold value, the conduction between the source electrode and the drain electrode is established such that the data voltage on the data line may be input to the pixel electrode to control the display of the corresponding pixel zone. A pixel unit of a conventional array substrate usually includes from bottom to top a substrate, a semi-conductive layer, an oxide layer, a gate electrode pattern, a first insulating layer, a second insulating layer, a source electrode pattern and a drain electrode pattern, an insulating protection layer and a pixel electrode. In order to make two conducting layers electrically connected, connecting holes may be made on the pixel unit.

As the development of the HDTV, the resolution ratio of the display has become higher and higher. High pixel density (pixels per inch, PPI) has become the main development direction of the display industry, which requires the connecting hole of the TFT device to be very small. In the related art, the connecting hole is mainly manufactured by patterning process. Specifically, a mask is placed on the photoresist of the conducting layer. Then the photoresist is exposed such that the photoresist may be patterned as the pattern of the mask. The photoresist is then developed. The exposed portion of the photoresist is removed while the un-exposed portion of the photoresist is kept such that the required pattern is formed. The remained photoresist is taken as a mask for etching the conducting layer to form the connecting hole. During the exposure process, the exposing time directly affects the whole time required for manufacturing the entire array substrate.

### SUMMARY

The present disclosure provides an array substrate and a method for manufacturing the same, which may help reduce the exposure time of the photoresist and improve its productivity.

According to an embodiment of the present disclosure, the array substrate may include: a first conducting layer comprising copper; a second conducting layer formed on the first conducting layer, wherein a reflectivity of the second conducting layer is higher than a reflectivity of the first conducting layer, the second conducting layer comprises any one of titanium, molybdenum, aluminum and silver, and a first thickness of the first conducting layer is at least greater than three times a second thickness of the second conducting layer; an insulating layer formed on the second conducting layer; a photoresist layer formed on the insulating layer defining a connecting hole, wherein the connecting hole extends through the photoresist layer and exposes the second conducting layer; and a third conducting layer, wherein the third conducting layer covers the connecting hole and is in contact with the second conducting layer.

According to an embodiment of the present disclosure, the array substrate manufacturing method may include: forming a second conducting layer on a first conducting layer, wherein a reflectivity of the second conducting layer is higher than a reflectivity of the first conducting layer; forming an insulating layer on the second conducting layer; forming a photoresist layer covering a whole surface of the insulating layer; exposing and developing the photoresist layer to form a first connecting hole, wherein the first connecting hole exposes the insulating layer; using the photoresist layer as a masking layer for etching the insulating layer to form a second connecting hole, wherein the second connecting hole exposes the second conducting layer; and forming a third conducting layer on the photoresist layer, wherein the third conducting layer covers the first connecting hole and the second connecting hole and is in contact with the second conducting layer.

According to an embodiment of the present disclosure, the array substrate may include: a first conducting layer; a second conducting layer formed on the first conducting layer, wherein a reflectivity of the second conducting layer is higher than a reflectivity of the first conducting layer; an insulating layer formed on the second conducting layer; a photoresist layer formed on the insulating layer defining a connecting hole, wherein the connecting hole extends through the photoresist layer and exposes the second conducting layer; and a third conducting layer, wherein the third conducting layer covers the connecting hole and is in contact with the second conducting layer.

By forming a second conducting layer on a first conducting layer where the connecting hole is to be formed and making the second conducting layer to have a higher reflectivity than the first conducting layer, the reflection of light on the second conducting layer may be increased during the exposure of the photoresist such that the light energy received by the photoresist may also be increased. Therefore, the implementation of the present disclosure may reduce the exposure time and improve productivity.

### BRIEF DESCRIPTION OF THE DRAWINGS

FIG. 1 is a section view of the array substrate according to an embodiment of the present disclosure.

FIG. 2 is a flow chart of the array substrate manufacturing method according to an embodiment of the present disclosure.

FIG. 3 shows a scenario of the manufacturing process of the array substrate according to FIG. 2.

FIG. 4 is a schematic diagram of the display panel according to an embodiment of the present disclosure.

### DETAILED DESCRIPTION

The main purpose of the present disclosure is to form on the conducting layer another conducting layer which has a higher reflectivity. When the photoresist layer is exposed, the conducting layer having a higher reflectivity may increase the reflection of light and the light energy received by the photoresist. Since the exposure dose is equal to the product of the exposure light energy and the exposure time, the implementation of the present disclosure may reduce the exposure time.

Taking the array substrate as an example, the technical solution of various embodiments of the present disclosure will be clearly and completely described with reference to the accompanying drawings. In the absence of conflict, the following embodiments and their technical features may be combined with each other. Also, directional terms such as “on” and “below” as used herein are used for better description and are not intended to limit the protection scope of the present disclosure.

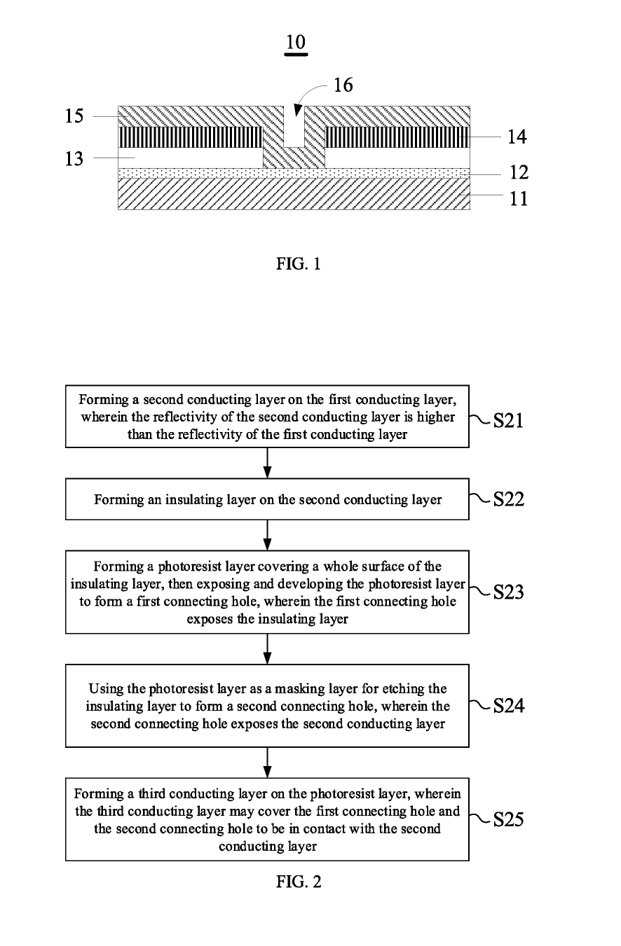

FIG. 1 is a section view of the array substrate according to an embodiment of the present disclosure. As shown in FIG. 1, in this embodiment, the array substrate 10 may include a first conducting layer 11, a second conducting layer 12, an insulating layer 13 a photoresist layer 14 and a third conducting layer 15 subsequently arranged one on another. A connecting hole 16 which exposes the second conducting layer 12 may be defined cooperatively by the photoresist layer 14 and the insulating layer 13. The third conducting layer 15 may extend through the connecting hole 16 and be in contact with the second conducting layer 12. Therefore, during the driving process of the array substrate 10, the third conducting layer 15 may be electrically connected to the second conducting layer 12 and the first conducting layer 11.

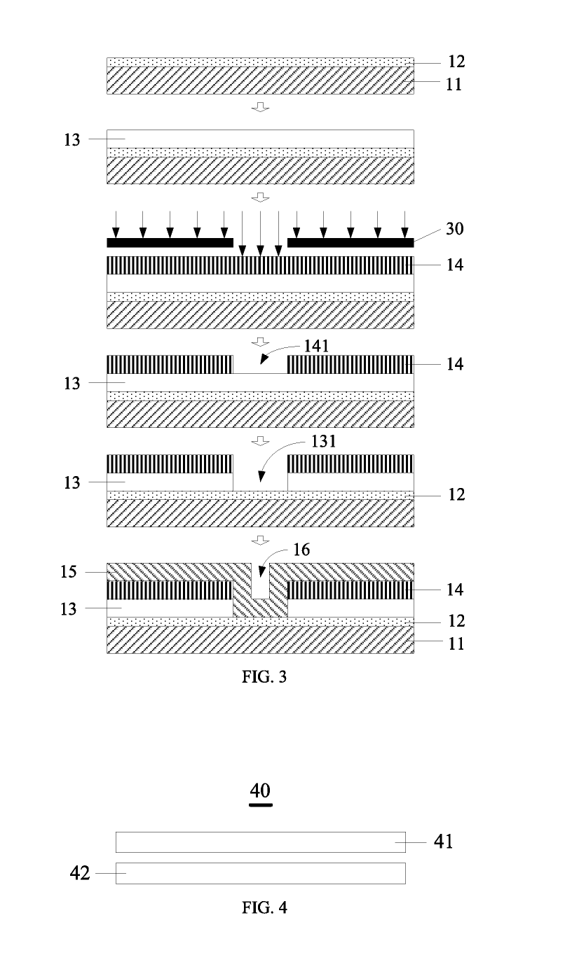

The connecting hole 16 may be formed by patterning process. In the following, a method for manufacturing the array substrate 10 and the connecting hole 16 will be described with reference to the combination of FIGS. 2 and 3.

As shown in FIG. 2, the method for manufacturing the array substrate 10 may include blocks S21˜S25.

S21: Forming a second conducting layer on the first conducting layer, wherein the reflectivity of the second conducting layer is higher than the reflectivity of the first conducting layer.

S22: Forming an insulating layer on the second conducting layer.

S23: Forming a photoresist layer covering a whole surface of the insulating layer, then exposing and developing the photoresist layer to form a first connecting hole, wherein the first connecting hole may expose the insulating layer.

S24: Using the photoresist layer as a masking layer for etching the insulating layer to form a second connecting hole, wherein the second connecting hole exposes the second conducting layer.

S25: Forming a third conducting layer on the photoresist layer, wherein the third conducting layer may extend through the first connecting hole and the second connecting hole to be in contact with the second conducting layer.

As shown in FIGS. 2 and 3, a mask 30 may be placed on the second conducting layer 12 (on which the photoresist layer 14 has been formed). The photoresist layer 14 may be made of positive photoresist. After being exposed, the photoresist layer 14 may be patterned as the pattern of the mask 30. Then the photoresist layer 14 may be developed. An exposed portion of the photoresist layer 14 may be removed while an un-exposed portion of the photoresist layer 14 is kept, such that the first connecting hole 141 may be formed. The remained portion of the photoresist layer 14 may be taken as mask for etching of the insulating layer 13 such that the second connecting hole 131 may be formed on the insulating layer 13. The second connecting hole 131 may be connected to the first connecting hole 141 such that the connecting hole 16 may be defined.

During the exposure of the photoresist layer 14, light (such as UV light) may pass subsequently the photoresist layer 14 and the insulating layer 13 and reach an upper surface of the second conducting layer 12. Then the light may be reflected by the upper surface of the second conducting layer 12 towards the lower surface of the photoresist layer 14. Since the reflectivity of the second conducting layer 12 is higher than that of the first conducting layer 11, compared to the first conducting layer 11, the arrangement of the second conducting layer 12 may increase the reflection of light and the exposure light energy received by the photoresist layer 14. Given that the exposure dose is equal to the product of the exposure light energy and the exposure time, the implementation of the present disclosure may reduce the exposure time and improve productivity.

The first conducting layer 11 and the second conducting layer 12 may be made of metal. For example, the first conducting layer 11 may be made of copper while the second conducting layer 12 may be correspondingly made of any one of titanium, molybdenum, aluminum and silver. Alternatively, the first conducting layer 11 may be made of aluminum while the second conducting layer may be correspondingly made of silver. In this embodiment, the process for forming the first conducting layer 11 and the second conducting layer 12 is not limited. For example, sputtering may be utilized. Moreover, during the forming of the first conducting layer 11 and the second conducting layer 12, reductive gases such as hydrogen may be utilized to prevent the material from oxidation.

Furthermore, in order to make the array substrate 10 lighter and thinner, the thickness of the second conducting layer 12 and that of the first conducting layer 11 may be predetermined. For example, when the sum of the thicknesses of the second conducting layer 12 and the first conducting layer 11 is greater than 250 nm, the thickness M₁ of the first conducting layer 11 may be at least greater than three times the thickness M₂ of the second conducting layer 12. That is, M₁+M₂>250 nm and M₁>3*M₂.

Based on the above-mentioned method, the first conducting layer 11, the second conducting layer 12, the insulating layer 13, the photoresist layer 14 and the third conducting layer 15 may be the structures of different layers of the array substrate 10. For example, the first conducting layer 11 may be the source electrode pattern or the drain electrode pattern of the TFT. The insulating layer 13 may be the passivation layer of the TFT. The photoresist layer 14 may be the planarization layer of the TFT. The third conducting layer 15 may be the pixel electrode layer. The manufacturing method and placement of the structures of each layer may be found in related arts and will not be described hereon.

Furthermore, the above-mentioned manufacturing method may also be utilized for the photoresist layer made of negative photoresist. In this case, the exposure position is different from the exposure position for the photoresist layer made of positive photoresist.

The present disclosure further provides a display panel. As shown in FIG. 4, the display panel 40 may include a first substrate 41 and a second substrate 42. The above-mentioned substrate 10 may be any one of these two substrates. Therefore, the display panel 40 also has similar advantages.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

1. A thin film transistor (TFT) array substrate, comprising:
a first conducting layer having a first reflectivity and a first thickness;
a second conducting layer formed on the first conducting layer, wherein the second conducting layer has a second reflectivity greater than the first reflectivity and a second thickness, wherein the first thickness of the first conducting layer is at least three times the second thickness of the second conducting layer;
an insulating layer formed on the second conducting layer;
a photoresist layer formed on the insulating layer, wherein the photoresist layer and the insulating layer cooperatively define a connecting hole extending to the second conducting layer; and
a third conducting layer formed on the photoresist layer, wherein the third conducting layer extends through the connecting hole and contacts the second conducting layer.

2. The array substrate of claim 1, wherein the first conducting layer comprises a source electrode pattern and a drain electrode pattern of a TFT.

3. The array substrate of claim 2, wherein the insulating layer is a passivation layer of the TFT, the photoresist layer is a planarization layer of the TFT, and the third conducting layer is a pixel electrode layer.

4. The array substrate of claim 1, wherein the photoresist layer comprises any one of negative photoresist and positive photoresist.

5. A thin film transistor (TFT) array substrate manufacturing method, comprising:
forming a second conducting layer on a first conducting layer, wherein the second conducting layer has a second reflectivity greater than a first reflectivity of the first conducting layer;
forming an insulating layer on the second conducting layer;
forming a photoresist layer covering a whole surface of the insulating layer, then exposing and developing the photoresist layer to form a first connecting hole, wherein the first connecting hole exposes the insulating layer;
etching the insulating layer with the photoresist layer as a masking layer to form a second connecting hole, wherein the second connecting hole extends to the second conducting layer; and
forming a third conducting layer on the photoresist layer, wherein the third conducting layer extends through the first connecting hole and the second connecting hole and contacts the second conducting layer.

6. The method of claim 5, wherein the first conducting layer comprises a source electrode pattern and a drain electrode pattern of a TFT.

7. The method of claim 6, wherein the insulating layer is a passivation layer of the TFT, the photoresist layer is a planarization layer of the TFT, and the third conducting layer is a pixel electrode layer.

8. The method of claim 5, wherein the photoresist layer comprises any one of negative photoresist and positive photoresist.

9. The method of claim 5, wherein the first conducting layer comprises copper and the second conducting layer comprises any one of titanium, molybdenum, aluminum and silver.

10. The method of claim 5, wherein the first conducting layer comprises aluminum, and the second conducting layer comprises silver.

11. The method of claim 5, wherein a first thickness of the first conducting layer is at least greater than three times a second thickness of the second conducting layer.

12. A thin film transistor (TFT) array substrate, comprising:
a first conducting layer having a first reflectivity and a first thickness;
a second conducting layer formed on the first conducting layer, wherein the second conducting layer has a second thickness and a second reflectivity greater than the first reflectivity of the first conducting layer;
an insulating layer formed on the second conducting layer;
a photoresist layer formed on the insulating layer, wherein the photoresist layer and the insulating layer cooperatively define a connecting hole and extending to the second conducting layer; and
a third conducting layer formed on the photoresist layer, wherein the third conducting layer extends through the connecting hole and contacts the second conducting layer.

13. The array substrate of claim 12, wherein the first conducting layer comprises a source electrode pattern and a drain electrode pattern of a TFT.

14. The array substrate of claim 13, wherein the insulating layer is a passivation layer of the TFT, the photoresist layer is a planarization layer of the TFT, and the third conducting layer is a pixel electrode layer.

15. The array substrate of claim 12, wherein the photoresist layer comprises negative photoresist or positive photoresist.

16. The array substrate of claim 12, wherein the first conducting layer comprises copper and the second conducting layer comprises any one of titanium, molybdenum, aluminum and silver.

17. The array substrate of claim 12, wherein the first conducting layer comprises aluminum, and the second conducting layer comprises silver.

18. The array substrate of claim 12, wherein the first thickness of the first conducting layer is at least three times the second thickness of the second conducting layer.

19. The array substrate of claim 1, wherein the first conducting layer comprises copper and the second conducting layer comprises any one of titanium, molybdenum, aluminum and silver.

20. The array substrate of claim 1, wherein the first conducting layer comprises aluminum, and the second conducting layer comprises silver.
